(19) United States
(12) Patent Application Publication
(10) Pub. No.: US 2003/0085728 A1
(43) Pub. Date: May 8, 2003

(54) Device for making pass/fail judgement of semiconductor integrated circuit

(76) Inventor: Tatsuo Takebayashi, Tokyo (JP)

Correspondence Address: MCDERMOTT WILL & EMERY, 600 13TH STREET, N.W., WASHINGTON, DC, 20005-3096, US

(21) Appl. No.: 10/139,652

(22) Filed: May 7, 2002

(30) Foreign Application Priority Data
Nov. 2, 2001 (JP) 2001-338156

(51) Int. Cl. G01R 31/26

(52) U.S. Cl. 324/765

(57) ABSTRACT

A pass/fail judgement device for a semiconductor integrated circuit has a measuring unit for supplying a chip transferred to a measuring position with measuring electric power, making the pass/fail judgement on measurement items in terms of critical values set in advance on the basis of measured data obtained from the chip, and outputting the judgement result and the measured data, and the pass/fail judgement unit for getting the measured data and the coordinate signal of chip and for making the pass/fail judgement for the chip on measurement items other than the foregoing measurement item in terms of critical values different from the foregoing critical value.

### BACKGROUND OF THE INVENTION

1. Field of the Invention

The present invention relates to a device for making a pass/fail judgement on a semiconductor integrated circuit and, in particular, a device which can make a comprehensive judgement for judgement results obtained by an arbitrary number of measurements on specific measurement items and which can change evaluation conditions on the basis of results of the comprehensive evaluation.

2. Description of the Related Art

Conventionally, a semiconductor integrated circuit is manufactured through steps of: a wafer process, a wafer test (intermediate test), an assembling (molding) process, and a final test. FIG. 7 is a schematic diagram to show the wafer test (intermediate test) in the prior art technology. In FIG. 7, a reference numeral 101 denotes a wafer and, as shown in FIG. 8, the wafer 101 includes a cluster of chips 102 consitituting a semiconductor integrated circuit. A reference numeral 103 denotes a wafer-bearing base movable in the two axial directions of x-axis and y-axis, a reference numeral 104 denotes a measuring unit for measuring the electric characteristics and operating characteristics of the chip 102. A reference numeral 105 denotes a measuring jig mounted on the measuring unit 104 and, as shown in FIG. 9, many probes 106 directly touching the chip 102 at a measuring position are mounted in a projecting manner on the peripheral portion of measuring jig 105. A reference numeral 107 denotes a transfer unit for moving the wafer-bearing base 103 to transfer the chip 102 to a position opposite to the measuring jig 105. A reference numeral 108 denotes a marking unit for receiving a judgement result combined with a coordinate signal of the chip 102 from the measuring unit 104 and for marking a failing chip with a failing mark.

The measuring unit 104 has a calculation block 111, such as CPU or the like, which supplies measuring electric power (measuring voltage or measuring current) to the measuring jig 105, and gets measured data from the measuring jig 105 and makes a pass/fail judgement on each chip 102, and an calculation program memory 112 for storing an calculation program and the like including critical values for the pass/fail judgement by the CPU 111.

Next, operation of the device will be described.

The transfer unit 107 of semiconductor integrated circuit transfers one chip included in the wafer 101 to a measuring position opposite to the measuring jig 105 and puts a terminal fixing portion of the chip 102 into contact with the probes 106 of measuring jig 105. In this state, the measuring unit 104 supplies the probes 106 with measuring electric power (measuring voltage or measuring current) and makes the pass/fail judgement on the chip 102 for predetermined measurement items in terms of critical values set previously based on the measured data obtained from the probes 106. Then, when the chip 102 is a failing chip, the measuring unit 104 outputs a failing signal to the marking unit 108 and the marking unit 108 which receives the failing signal and the coordinate signal of chip 102 output from the transfer unit 107, marks the failing chip with a failing mark. In this manner, when the chips 102 are cut away from the wafer 101, thereby being single chips, this failing mark makes it easy to separate the failing chip from others.

A device for making the pass/fail judgement on a semiconductor integrated circuit in the prior art technology are constituted in the manner described above, thus the pass/fail judgement on a semiconductor integrated circuit is applied to each chip, and the critical values for the pass/fail judgement are set in an calculation program stored in a memory. Further, there is the case where it is desired that, for example, the critical value is set on a measurement item in consideration of variations in one wafer and that the pass/fail judgement is made by the set measurement item, but such pass/fail judgement can not be made by the device in the prior art technology.

Further, in the case of measurement items having large variations, if the critical values are loose, quality is made poor and if the critical values are made rigorous, yield is reduced. Thus, usually, manufacturers of the semiconductor integrated circuits set the critical values at values more rigorous than the specifications required by users and therefore if the pass/fail judgement on the chip is applied to all many measurement items in terms of these rigorous critical values, there is produced a problem that the yield might be unnecessarily seduced and can not be improved.

### SUMMARY OF THE INVENTION

The present invention has been made to solve the above mentioned problems in the prior art technology. It is an object of the present invention to provide a device for making a pass/fail judgement, in which the pass/fail judgement on a semiconductor integrated circuit can be applied to specific measurement items in terms of the critical values different from ordinary ones, in other words, in which the critical values are determined in comprehensive consideration of the judgement results of respective chips of the semiconductor integrated circuit by an arbitrary unit, for example, by one wafer or by one lot (collection of a predetermined number of wafers) thereby to prevent an unnecessary decrease in the yield.

A device for making the pass/fail judgement in accordance with the present invention has a transfer unit for transferring one of many chips included in a wafer to a measuring position and for outputting the coordinate signal of chip positioned at the measuring position; a measuring unit for supplying the chip transferred to the measuring position with measuring electric power and for making the pass/fail judgement for the chip on measurement items in terms of critical values set previously on the basis of measured data obtained from the chip and for outputting a measurement result and the measured data; and a pass/fail judgement unit for getting the measured data and the coordinate signal of chip and for making the pass/fail judgement for the chip on measurement items other than the foregoing measurement items in terms of critical values different from the foregoing critical values.

By this arrangement there is produced an effect for a specific measurement item, it is possible to arbitrarily set critical values suitable for the specific measurement item for making the pass/fail judgement and to prevent the yield from being reduced more than required in the range of a specification required by the user, as compared with the case where the pass/fail judgement is applied to all the measurement items in terms of the critical values set uniformly at a rigorous level.

### BRIEF DESCRIPTION OF THE DRAWINGS

FIG. 1 is a block diagram to show outline of a device for making a pass/fail judgement for semiconductor integrated circuit in accordance with an embodiment 1 of the present invention.

FIG. 2 is a block diagram to show the configuration of pass/fail judgement unit of the device.

FIG. 3 is a flowchart to explain the operation of embodiment 1.

FIG. 4 is a graph to show an effect of changing a critical value.

FIG. 5 is a block diagram to show the outline of a device for making the pass/fail judgement for a semiconductor integrated circuit in accordance with an embodiment 2 of the present invention.

FIG. 6 is a flowchart to explain the operation of embodiment 2.

FIG. 7 is a block diagram to show the outline of a device for making the pass/fail judgement for a semiconductor integrated circuit in the prior art technology.

FIG. 8 is a plan view to show a semiconductor wafer.

FIG. 9 is a plan view of chip separated from a wafer.

### DESCRIPTION OF THE PREFERRED EMBODIMENTS

The preferred embodiments in accordance with the present invention will be described below.

Embodiment 1

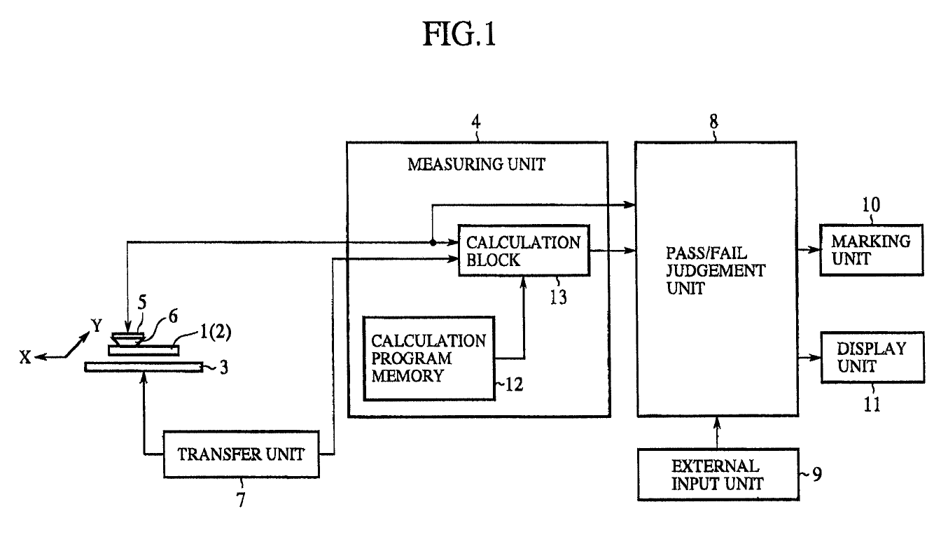

FIG. 1 is a schematic diagram to show a device for making a pass/fail judgement for a semiconductor integrated circuit in accordance with the present invention which conducts a wafer test (intermediate test). In FIG. 1, a reference numeral 1 denotes a wafer including a cluster of chips 2 constituting a semiconductor integrated circuit. A reference numeral 3 denotes a wafer-bearing base movable in the two axial directions of x-axis and y-axis, a reference numeral 4 denotes a measuring unit of semiconductor integrated circuit for measuring the electric characteristics and operating characteristics of the chip 2. A reference numeral 5 denotes a measuring jig mounted on the measuring unit 4 and, as shown in FIG. 9, many probes 6 directly touching the chip 2 at a measuring position are mounted in a projecting manner on the peripheral portion of measuring jig 5. A reference numeral 7 denotes a transfer unit of semiconductor integrated circuit for moving the wafer-bearing base 3 to transfer the chip 2 to a position opposite to the measuring jig 5. A reference numeral 8 denotes the pass/fail judgement unit for making the pass/fail judgement for the chip 2 on the specified measurement items for which a measurement is not made by the measuring unit 4, a reference numeral 9 denotes an external input unit for changing and inputting the critical values to the pass/fail judgement unit 8, a reference numeral 10 denotes a marking unit for marking the failing chip with a failing mark based on the judgement results from the pass/fail judgement unit 8 and the chip coordinate signals corresponding to the judgement results from the transfer unit 7, and a reference numeral 11 denotes a display unit for displaying the judgement results from the pass/fail judgement unit 8.

The measuring unit 4 has a calculation block 13, such as CPU or the like, which supplies the measuring jig 5 with measuring electric power (measuring voltage or measuring current) and gets measured data from the measuring jig 5 and makes the pass/fail judgement for each chip 2 on the basis of measured data, and an calculation program memory 12 for storing an calculation program and the like used for the pass/fail judgement for the calculation block 13.

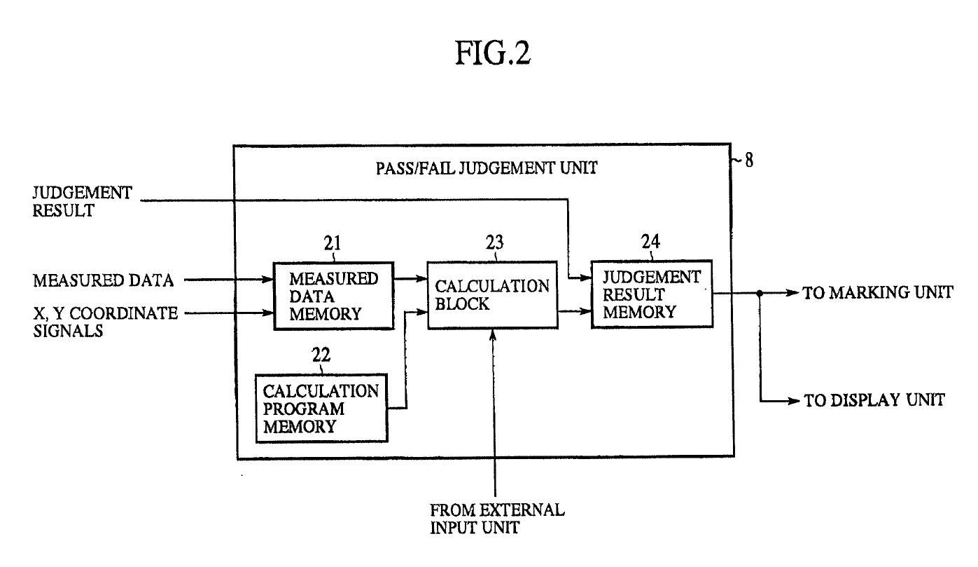

The pass/fail judgement unit 8, as shown in FIG. 2, has a measured data memory 21 which is supplied with the measured data from the measuring unit 4 and the X, Y coordinate signals of chip at the measuring position from the transfer unit 7 and stores the measured data and the X, Y coordinate signals in association with each other, an calculation program memory 22 for storing the initial critical values for the pass/fail judgement and an calculation program for the pass/fail judgement, a calculation block 23 for making the pass/fail judgement for each chip for the specific measurement items based on the output signals from the memories 21 and 22, and a judgement result memory 24 for storing the judgement results and displaying the stored contents on the display unit 11 at a time, for example, after making the pass/fail judgement for all the chips included in one wafer is finished.

Next, the operation of pass/fail judgement unit 8 will be described.

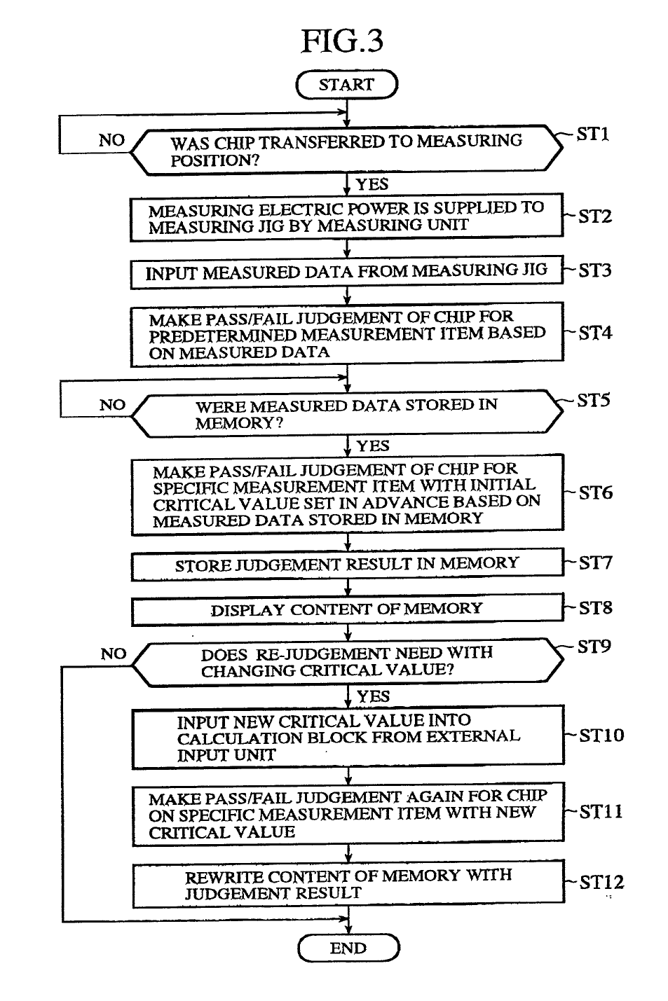

FIG. 3 is a flowchart to explain the operation of pass/fail judgement unit 8. First, it is confirmed whether or not one of the chips 21 included in a map 1 is transferred to a measuring position by the transfer unit 7 (step ST1). If the confirmed result is YES, the measuring unit 4 supplies the measuring jig 5 with measuring electric power (measuring voltage or measuring current) (step ST2). Then, measured data from the measuring jig 5 is input to the measuring unit 4 (step ST3) and the calculation block 13 makes the pass/fail judgement for the chip 2 for the desired measurement items in terms of the critical values set in the calculation program memory 12 (step ST4).

For example, in the case where there are the following measurement items:

Operating characteristics

A: (5 V, 20 kHz)

B: (3 V, 20 kHz)

C: (2 V, 10 kHz)

Electric characteristics

A: (amount of current: 10 mA or less)

B: (maximum rated voltage: up to 6 V)

C: (leakage current when operation stops)

when it is desired that for the measurement item C of electric characteristics, the critical value is set in consideration of variations in one wafer, for example, and then the pass/fail judgment is made, the foregoing measuring unit 4 makes the pass/fail judgement for the chip 2 only for the operating characteristics A, B, and C and the electric characteristics A and B, and then the pass/fail judgement unit 8 disposed at the latter stage makes the pass/fail judgement for the chip 2 for the electric characteristic C.

Then, the measuring unit 4 makes the pass/fail judgement for all the chips 2 included in one wafer 1 and confirms whether or not the measured data are stored in the measured data memory 21 (step ST5) and if the result is NO, the measuring unit 4 continues the measuring operation until it finishes making the pass/fail judgement for all the chips 2.

On the other hand, if the result is YES, the calculation block 23 makes the pass/fail judgement for the chip 2 on the measurement item of electric characteristic C as the specified measurement item in terms of the initial critical values set previously on the basis of measured data stored in the measured data memory 21 (step ST6). The judgement result is stored sequentially in the judgement result memory 24 (step ST7) and for example, when making the pass/fail judgment for all the chips 2 included in one wafer is finished, the judgement results accumulated in the judgement result memory 24 are displayed on the display unit 11 (step ST8), and it is confirmed from the displayed content whether or not it is necessary to change the critical value for making the pass/fail judgement again (stop ST9).

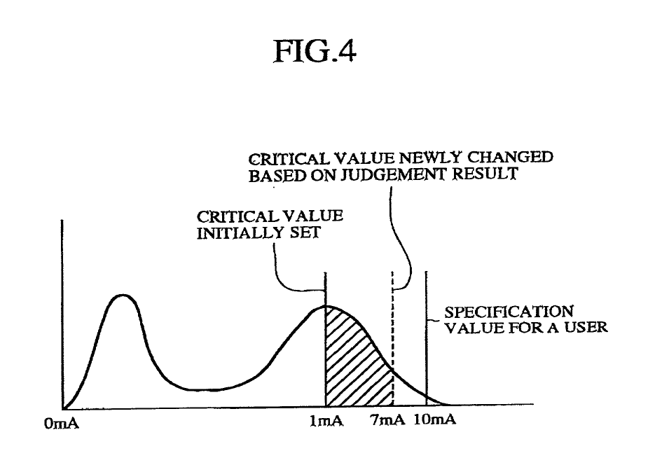

If the conformation result is NO, the evaluation operation is finished, and if the confirmed result is YES, a new critical value is input to the calculation block 23 by an external input unit 9 (step ST10) to set the new critical value. For example, as shown in FIG. 4, when the initial critical value is 1 mA and the specification value for user is 10 mA, a new critical value is set at 7 mA and the pass/fail judgement for the measured data accumulated in the measured data memory 21 described above, is applied to the measurement item of electric characteristic C in terms of the new critical value (step ST11) and the content of judgement result memory 24 described above is rewritten with the judgement result (step ST12). This is the end of pass/fail judgement operation.

As described above, in the embodiment 1, the pass/fail judgement for the judgement results of one wafer, a plurality of wafers or one lot is made in a comprehensive manner and the results of pass/fail judgement are displayed, and the critical value for the measurement item of electric characteristic C, which is a specific measurement item, is changed based on the displayed content, and the pass/fail judgement for the measured data is made again for the changed critical values of electric characteristic C. In this manner, the chips in the shaded region shown in FIG. 4 can be confirmed as no-defective chips for the measurement item of electric characteristic C, which is the specified measurement item. Therefore, it is possible to prevent the yield from decreasing and to avoid the yield from deteriorating as compared with the case where the pass/fail judgement for the measured data is applied to all the measurement items in the state of uniform rigorous critical values.

Embodiment 2

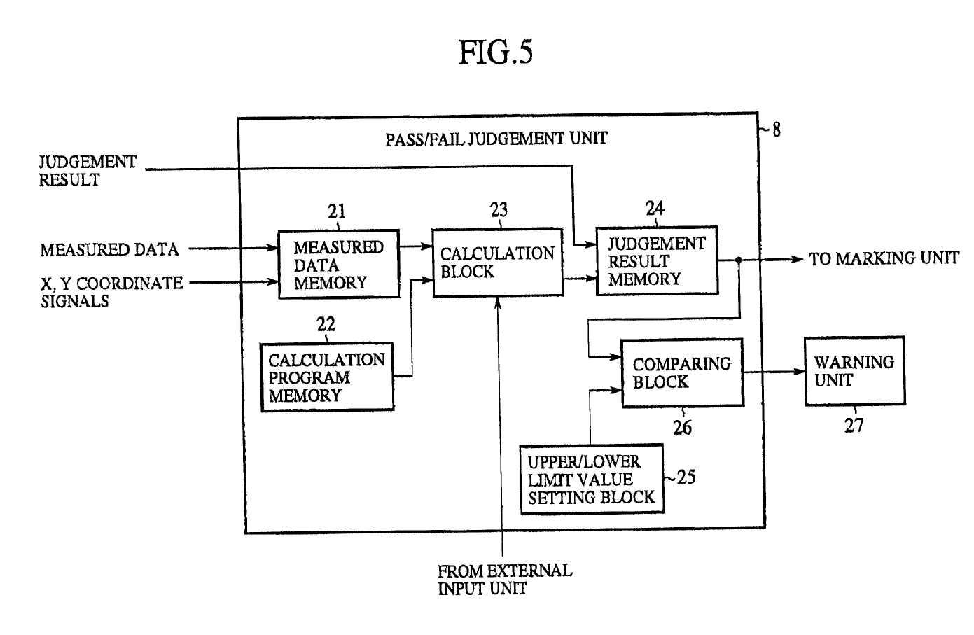

FIG. 5 is a schematic diagram to show a device for making a the pass/fail judgement for a semiconductor integrated circuit in accordance with the embodiment 2 of present invention and the same parts as in FIG. 1 are denoted by the same reference numerals and description on them will be omitted. In FIG. 5, a reference numeral 25 denotes an upper/lower limit value setting block for setting the upper and lower limit values (allowable range) for the judgement results, a reference numeral 26 denotes a comparing block for judging by comparison whether or not the judgement results of a previously set number of measurements exceed the upper or lower limit value, and a reference numeral 27 denotes a warning unit such as a buzzer or a lamp for giving a warning of occurrence for need of changing the critical value on the basis of output of the comparing block 26 when the judgement result exceeds the upper or lower limit value.

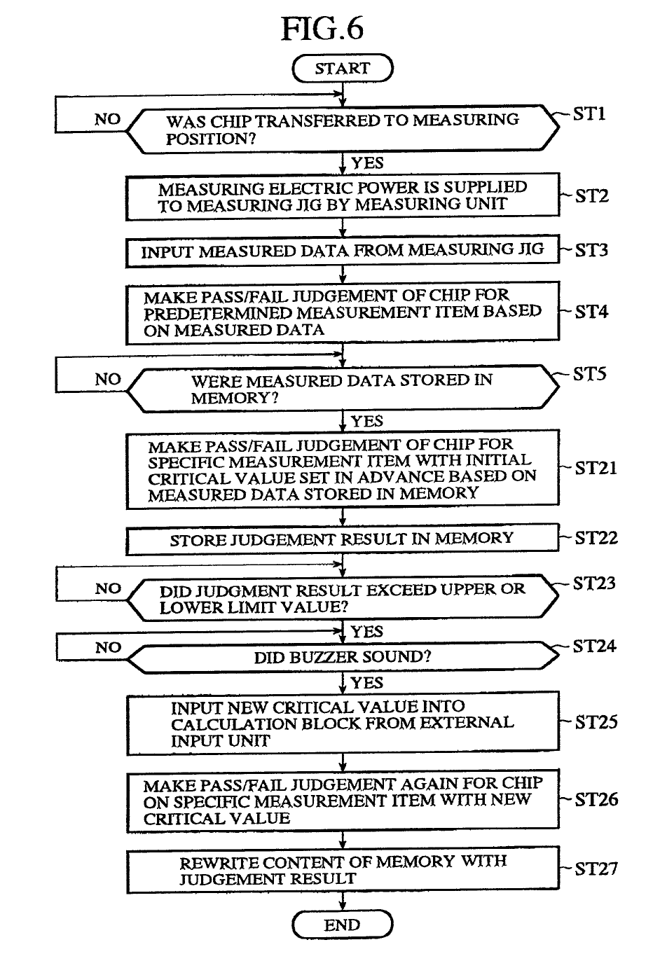

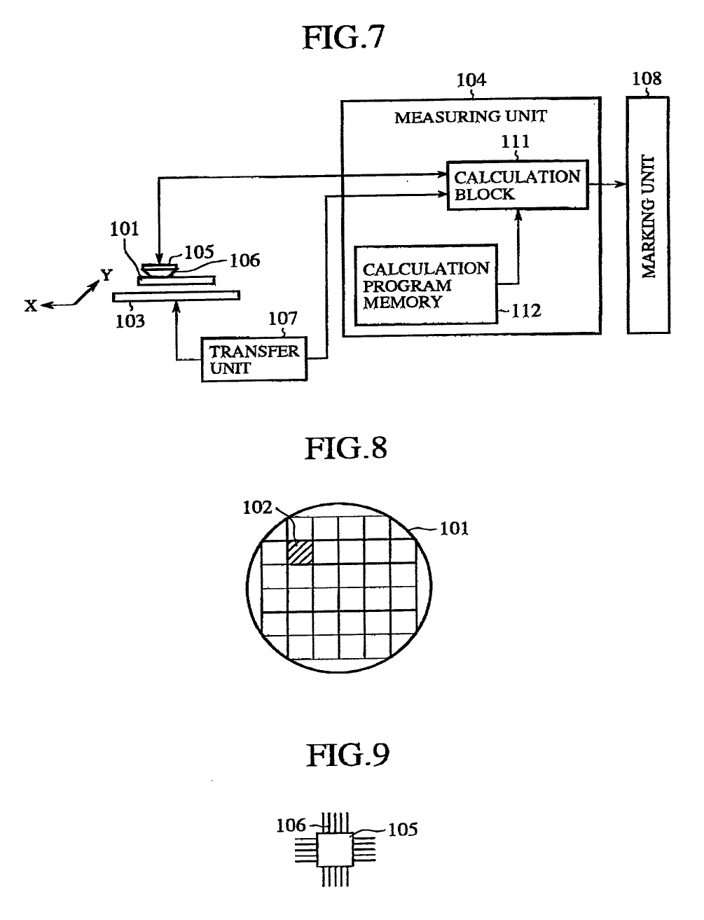

FIG. 6 is a flowchart to explain operation of the device for making the pass/fail judgement in the second embodiment. First, one of the chips 2 included in a wafer 1 is transferred to a measuring position and the pass/fail judgement for the chip 2 is made, and then the next chip 2 is transferred to the measuring position and the pass/fail judgement for the next chip 2 is made in sequence. In this manner, the operations until accumulating all the measured data of, for example, all the chips 2 included in the one wafer 1 in the measured data memory 21, that is, the operations from the steps ST1 to ST5 shown in FIG. 6 are the same operations as that of shown in FIG. 3, so the description of such operations will be omitted.

If the confirmed result of step ST5 is YES, the pass/fail judgement for chip 2 on the measurement item of electric characteristic C (specific measurement item) in terms of the initial critical value set previously, is made based on the measured data stored in the measured data memory 21 (step ST21). The judgement result is stored in sequence in the judgement result memory 24 (step ST22), and when the pass/fail judgement of, for example, all the chips 2 included in the one wafer 1 is finished, the comparing block 26 confirms whether or not the judgement results accumulated in the judgement result memory 24 exceed the upper or lower limit value read from the upper/lower limit value setting block 25 (step ST23).

If the confirmed result is YES, it is then confirmed whether the buzzer as the warning unit 27 sounds or not (step ST24) and if the confirmed result is YES, a new critical value is input to the calculation block 23 by the use of external input unit 9 (step ST25). For example, as shown in FIG. 4, in the case where the initial critical value is 1 mA and the specification value for the user is 10 mA, a new critical value is set at 7 mA and the pass/fail judgement for the measured data accumulated in the measured data memory 21 is made again for the measurement item of electric characteristic C (step ST26), and the contents of judgement result memory 24 are rewritten with the judgement results (step ST27). This is the end of pass/fail judgement operation.

According to the embodiment 2, in the case where the judgement results exceed the upper or lower limit value set in advance for the measurement item of electric characteristic C, which is the specific measurement item, a warning of exceeding the upper or lower limit value is given automatically and thus it is possible to change the initial critical value to the new critical value without fail and to surely prevent an unnecessary decrease in the yield.

According to the present invention, there is produced an effect to comprehensively evaluate the judgement results in terms of an arbitrary number of measurements, for example, one wafer, a plurality of wafers or one lot for making the pass/fail judgement according to the circumstances.

According to the present invention, there is produced an effect to change the critical value to a new critical value without fail for surely preventing an unnecessary decrease in the yield.

According to the present invention, there is produced an effect to make product quality supplied to the user always satisfy the specification required by the user with preventing the yield of a product from being decreased more than required.

According to the present invention, there is produced an effect to always suitably mark the chip.

What is claimed is:

1. A device for making a pass/fail judgement for semiconductor integrated circuit comprising:
a transfer unit for transferring one of many chips included in a wafer to a measuring position and outputting the coordinate signal of chip positioned at the measuring position;
a measuring unit for supplying said chip transferred to said measuring position with measuring electric power and for making the pass/fail judgement for said chip on measurement items in terms of critical values set previously based on measured data obtained from said chip and for outputting the judgement result and said measured data; and
a pass/fail judgement unit for getting said measured data and said coordinate signal of the chip and for making the pass/fail judgement for said chip on measurement item other than said measurement item in terms of critical values different from said critical values.

2. A device for making the pass/fail judgement for a semiconductor integrated circuit according to claim 1, wherein said pass/fail judgement unit comprises a measured data memory for storing the measured data of respective chips output from the measuring unit, a calculation block for making the pass/fail judgement for the content of measured data memory in terms of initial critical value set in advance, and a judgement result memory for storing the judgement result, and said device further comprising a display unit for displaying the judgement result and an external input unit for changing the initial critical value based on said displayed judgement result.

3. A device for making the pass/fail judgement for a semiconductor integrated circuit according to claim 1, wherein said pass/fail judgement unit comprises a measured data memory for storing the measured data of respective chips output from the measuring unit, a calculation block for making the pass/fail judgement for the content of measured data memory in terms of initial critical value set in advance, a judgement result memory for storing the judgement result, an upper/lower limit value setting block for setting the allowable range of judgement result, and a comparing block for judging by comparison whether or not the judgement results of a previously set number of measurements exceed the upper or lower limit value of allowable range, and said device further comprising a warning unit for giving a warning of changing said initial critical value based on output of said comparing block when the judgement results exceed said upper or lower limit value.

4. A device for making the pass/fail judgement for a semiconductor integrated circuit according to claim 2, wherein the initial critical value is changed in the range of a specification required by user.

5. A device for making the pass/fail judgement for a semiconductor integrated circuit according to claim 1, wherein the chip necessary for being marked is marked based on the judgement result.
